(19) United States
(12) Patent Application Publication
(10) Pub. No.: US 2026/0213491 A1
(43) Pub. Date: Jul. 23, 2026

(54) ADAPTIVE PRE-BIASING OF A DIODE

(71) Applicant: STMicroelectronics International N.V., Geneva (CH)

(72) Inventors: Vratislav MICHAL, Fontanil-Cornillon (FR); Nicolas MARTY, Saint Egreve (FR)

(21) Appl. No.: 19/035,204

(22) Filed: Jan. 23, 2025

(51) Int. Cl. H01S 5/042; G01S 17/894; H01S 5/026; H01S 5/062; H01S 5/183

(52) U.S. Cl. CPC H01S 5/0428; G01S 17/894; H01S 5/026; H01S 5/06216; H01S 5/183

(57) ABSTRACT

In accordance with various embodiments of the present disclosure, a pre-biasing circuit is provided. In some embodiments, the pre-biasing circuit comprises a capacitor circuit connected between a common node and ground; a diode connected in parallel with the capacitor circuit; a derivative circuit connected to the common node; a summing circuit; a pre-biasing current source; and a test voltage source. The test voltage source outputs a test voltage to the summing circuit, causing the pre-biasing current source to inject a test current into the common node. If a voltage at the common node is less than a forward voltage of the diode, the injected test current causes the voltage at the common node to increase, causing the derivative circuit to output a voltage to the summing circuit corresponding to a rate of increase of the voltage, causing the pre-biasing current source to inject a pre-biasing current into the common node.

### FIELD OF THE INVENTION

Example embodiments of the present disclosure relate generally to laser diodes and, more particularly, drivers for laser diodes.

### BACKGROUND

A time-of-flight (ToF) sensor is a range imaging camera system for measuring distances between the camera and a subject based on the round-trip time of an artificial light signal. ToF sensors are often used in mobile devices, such as smartphones, to provides features such as camera autofocus and facial recognition. The artificial light for such ToF sensors is typically provided by a vertical-cavity surface-emitting laser (VCSEL). Such a VCSEL comprises a laser diode.

A high-speed driver is utilized to drive current into the VSCEL. In such a high-speed VCSEL driver, a switched-mode direct current-to-direct current (DC/DC) power converter is utilized to drive current into the laser diode. In some cases, the output node of the DC/DC converter contains an output capacitor which is connected in parallel to the laser diode.

In this usual case, at the start of operation, the capacitor voltage is typically zero, indicating that the capacitor is discharged. When the driver receives a request to generate a laser pulse, the DC/DC converter first pre-charges the output capacitor. Only when the voltage across the output capacitor reaches the forward voltage (V_{F}) of the VCSEL does the DC/DC converter start regulating the VCSEL current. That is, until the voltage across the output capacitor reaches the forward voltage of the VCSEL, no current from the DC/DC generator will flow to the laser diode and therefore the laser diode will not produce any light until that time.

The time it takes to pre-charge the output capacitor to the forward voltage of the VCSEL can cause an unacceptable delay in activation of the ToF sensor. For this reason, it is desirable to pre-bias the voltage across the output capacitor to V_{F}. Pre-biasing the voltage across the output capacitor is challenging because V_{F} can vary based on a variety of factors, such as temperature, and is generally unknown and impossible to measure.

Applicant has identified many technical challenges and difficulties associated with pre-biasing the output capacitor of a laser diode driver. Through applied effort, ingenuity, and innovation, Applicant has solved problems related to pre-biasing the output capacitor of a laser diode driver by developing solutions embodied in the present disclosure, which are described in detail below.

### BRIEF SUMMARY

Various embodiments described herein relate to circuits, devices, and methods for pre-biasing the output capacitor of a laser diode driver.

In accordance with various embodiments of the present disclosure, a pre-biasing circuit is provided. In some embodiments, the pre-biasing circuit comprises a capacitor circuit connected between a common node and a ground; a diode connected in parallel with the capacitor circuit between the common node and the ground; a derivative circuit having an input and an output, the input being connected to the common node; a summing circuit having a first input, a second input, and an output, the first input being connected to the output of the derivative circuit; a pre-biasing current source with an input connected to the output of the summing circuit and an output connected to the common node; and a test voltage source having an output connected to the second input of the summing circuit. The test voltage source is configured to output a predetermined test voltage for a predetermined amount of time to the second input of the summing circuit, which in turn causes the pre-biasing current source to inject a test current into the common node. If a voltage at the common node is less than a forward voltage of the diode, the injected test current causes the voltage at the common node to increase, which in turn causes the derivative circuit to output a voltage corresponding to a rate of increase of the voltage at the common node to the first input of the summing circuit, which in turn causes the pre-biasing current source to inject a pre-biasing current into the common node. If the voltage at the common node is equal to or greater than the forward voltage of the diode, the voltage at the common node will not increase, which in turn causes the derivative circuit to not output a voltage to the first input of the summing circuit, which in turn causes the pre-biasing current source to not inject a pre-biasing current into the common node.

In some embodiments, the circuit further comprises an operating current source having an output connected to the common node to provide an operating current to drive the diode.

In some embodiments, the operating current source comprises a direct current-to-direct current converter.

In some embodiments, the pre-biasing current is limited to a predefined maximum pre-biasing current.

In some embodiments, the circuit further comprises an auxiliary current source connected in parallel to the pre-biasing current source and having an output connected to the common node to provide a predefined pre-bias maintenance current to the common node.

In some embodiments, the diode comprises one or more silicon diodes, one or more laser diodes, or one or more light emitting diodes.

In some embodiments, the one or more laser diodes comprise one or more vertical cavity surface emitting lasers.

In accordance with various embodiments of the present disclosure, a time-of-flight module is provided. In some embodiments, the time-of-flight module comprises a capacitor circuit connected between a common node and a ground; a laser diode circuit connected in parallel with the capacitor circuit between the common node and the ground; a derivative circuit having an input and an output, the input being connected to the common node; a summing circuit having a first input, a second input, and an output, the first input being connected to the output of the derivative circuit; a pre-biasing current source with an input connected to the output of the summing circuit and an output connected to the common node; and a test voltage source having an output connected to the second input of the summing circuit. The test voltage source is configured to output a predetermined test voltage for a predetermined amount of time to the second input of the summing circuit, which in turn causes the pre-biasing current source to inject a test current into the common node. If a voltage at the common node is less than a forward voltage of the laser diode circuit, the injected test current causes the voltage at the common node to increase, which in turn causes the derivative circuit to output a voltage corresponding to a rate of increase of the voltage at the common node to the first input of the summing circuit, which in turn causes the pre-biasing current source to inject a pre-biasing current into the common node. If the voltage at the common node is equal to or greater than the forward voltage of the laser diode circuit, the voltage at the common node will not increase, which in turn causes the derivative circuit to not output a voltage to the first input of the summing circuit, which in turn causes the pre-biasing current source to not inject a pre-biasing current into the common node.

In accordance with various embodiments of the present disclosure, a method of pre-biasing a diode is provided. In some embodiments, the method of pre-biasing a diode module comprises providing a pre-biasing circuit as described above; and outputting a predetermined test voltage for a predetermined amount of time from the test voltage source to the second input of the summing circuit, which causes the pre-biasing current source to inject a test current into the common node. If a voltage at the common node is less than a forward voltage of the diode, the injected test current causes the voltage at the common node to increase, which in turn causes the derivative circuit to output a voltage corresponding to a rate of increase of the voltage at the common node to the first input of the summing circuit, which in turn causes the pre-biasing current source to inject a pre-biasing current into the common node. If the voltage at the common node is equal to or greater than the forward voltage of the diode, the voltage at the common node will not increase, which in turn causes the derivative circuit to not output a voltage to the first input of the summing circuit, which in turn causes the pre-biasing current source to not inject a pre-biasing current into the common node.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1 is a block diagram of an example system for pre-biasing a laser diode driver, in accordance with some embodiments of the present disclosure;

FIG. 2 timing diagram of signals in the example system of FIG. 1, in accordance with some embodiments of the present disclosure;

FIG. 3 is a circuit diagram of an example system for pre-biasing a laser diode driver, in accordance with some embodiments of the present disclosure; and

FIG. 4 is a circuit diagram of an example system for pre-biasing a laser diode driver, in accordance with some other embodiments of the present disclosure.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

Various embodiments of the present disclosure overcome the above technical challenges and difficulties and provide various technical improvements and advantages based on, for example, but not limited to, providing example circuits, devices, and methods for pre-biasing a laser diode driver. Various embodiments of the present disclosure may be implemented in any suitable device having one or more laser diodes (such as VCSELs), including but not limited to ToF modules. Embodiments of the present disclosure are described herein in relation to VCSELs, VCSEL drivers, and ToF modules, however, embodiments of the present disclosure are not limited to use with VCSELs, VCSEL drivers, and ToF modules. Various embodiments of the present disclosure may also be used to pre-bias any other suitable type of diode, including but not limited to, silicon diodes, light emitting diodes (LEDs), and superluminescent diodes.

In various embodiments, a laser diode (e.g., VCSEL) driver circuit applies a test current to a common node of an output capacitor (Cout) and a laser diode connected in parallel, that represents the output node of the pulsating DC/DC converter (the common node may also be termed an output node), to determine if the voltage across Cout is less than the forward voltage (Vf) of the laser diode by detecting a rise in the voltage across Cout (such as via a derivative circuit), provides a pre-charging current to the common node if the voltage across Cout is rising (and therefore the voltage across Cout is less than Vf) in order to charge (pre-bias) Cout, determines if the voltage across Cout is equal to the forward voltage (Vf) of the laser diode by detecting no significant change in the voltage across Cout, and stops providing a current to the common node if the voltage across Cout is no longer rising (and therefore the voltage across Cout reached Vf).

Embodiments of the present disclosure are able to accurately pre-bias the output capacitor of a VCSEL driver regardless of the forward voltage of the laser diode or whether the forward voltage of the laser diode is changing due to, for example, temperature. In this regard, embodiments of the present disclosure provide what may be termed adaptive pre-biasing. The goal is to deliver a large pre-biasing current (e.g. 50 mA) to Cout, but limit the current to the laser diode so as not to produce any stray light output before it is desired.

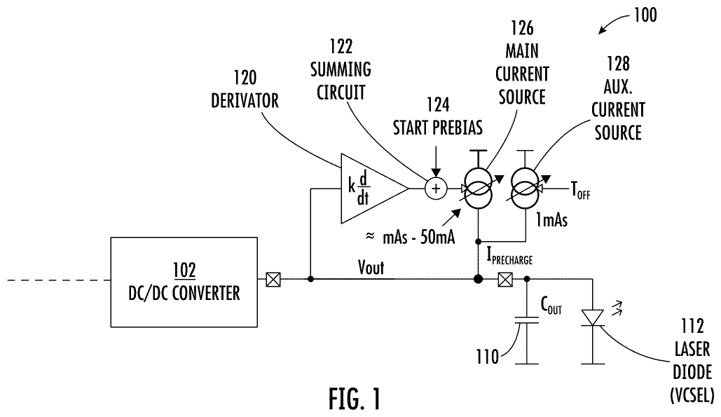

FIG. 1 is a block diagram of an example system for adaptive pre-biasing of a laser diode driver, in accordance with some embodiments of the present disclosure. As illustrated in FIG. 1, the system 100 comprises a DC/DC converter 102, an output capacitor (Cout) 110, and a laser diode 112 in parallel with Cout 110. The output node of the DC/DC converter 102 is a common node with Cout 110 and the laser diode 112. The DC/DC converter 102 drives regulated pulsating current into the laser diode 112.

In accordance with embodiments of the present disclosure, the system 100 further comprises a derivative circuit (termed a derivator) 120 with a high gain, a summing circuit 122, and a voltage controlled current source (VCCS) 126. The input of the derivator 120 and the output of the VCCS 126 are connected to the common node of Cout and the laser diode.

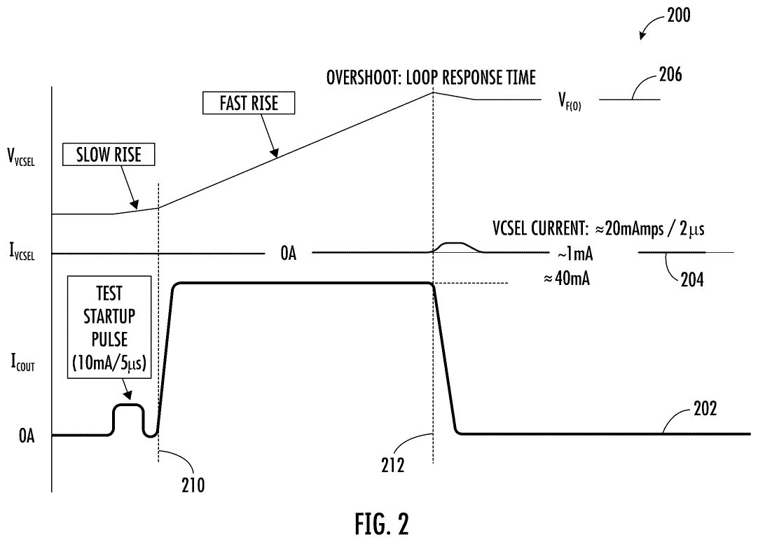

FIG. 2 illustrates a timing diagram 200 showing the voltages and currents in the system 100 during pre-biasing. In FIG. 2, V_{VCSEL} 206 is the voltage at the common node of Cout 110 and the laser diode 112 (so also the voltage across Cout (which may also be termed Vout) which is to be pre-biased to the target V_{OUT}=Vf), I_{VCSEL} 204 is the current through the laser diode 112, and I_{COUT} 202 is the current through Cout 110.

In various embodiments, to begin the pre-biasing procedure, a “Start pre-bias” voltage 124 is applied to the summing circuit 122 for a short period of time (e.g., 5 microseconds) to cause the VCCS 126 to inject a test current (e.g. 5-40 mA) to the common node of Cout 110 and the laser diode 112. If V_{VCSEL} 206 does not significantly rise when this test current is injected, this means that the test current is flowing into the laser diode which means that V_{VCSEL} 206 is equal to Vf of the VCSEL and no pre-biasing is needed. However, if V_{OUT} rises when the test current is injected, this means that V_{VCSEL} 206 is less than Vf and that Cout needs to be charged (i.e., pre-biased). In the first section of FIG. 2 (before the first vertical dashed line 210), the test current pulse can be seen as well as the beginning of the rise of V_{VCSEL} 206. In various embodiments, the test pulse can vary in amplitude and also in duration, and may overlap with the main precharge phase.

The rise of V_{VCSEL} 206 is detected by the derivator 120. If the derivator 120 determines that the derivative dV_{VCSEL}/dt is positive, the derivator 120 provides an output to the summing circuit 122 and the main voltage controlled current source 126 produces a high current and keeps charging Cout 110. In various embodiments, the output of the VCCS 126 is clamped and therefore has a maximum output (e.g., 40 mA). Thus, even if the “Start pre-bias” voltage 124 is still being applied to the summing circuit 122 when the derivator 120 begins detecting a rise in V_{VCSEL} 206 and providing an output to the summing circuit 122, the output of the VCCS 126 will be limited to its maximum (clamped) output value.

In the second section of FIG. 2 (between the two vertical dashed lines 210, 212), V_{VCSEL} 206 continues to rise more rapidly, the derivator 120 detects this rise and drives the VCCS 126 to its maximum value (40 mA in this example), thereby continuing to charge Cout 110. The current I_{VCSEL} 204 through the laser diode 112 is still zero because V_{VCSEL} 206 is less than Vf. As long as V_{VCSEL} 206 is less than Vf, V_{VCSEL} 206 will continue to rise and the derivator will continue to drive the VCCS 126, thereby charging Cout 110.

When the value of V_{VCSEL} 206 reaches Vf, all of the current from the VCCS 126 will flow through the laser diode 112 and none will flow through Cout 110. As such, V_{VCSEL} 206 will be clamped by the Vf, thus will stop rising, the derivator 120 will determine that the derivative dV_{VCSEL}/dt tends to zero, the derivator 120 will no longer provide an output to the summing circuit 122, and the VCCS 126 will no longer output a current.

This is seen in the third section of FIG. 2 (after the second vertical dashed line 212) in which V_{VCSEL} 206 levels out at Vf (after a brief overshoot) and I_{COUT} 202 drops to zero. A current briefly flows through the laser diode 112 until the VCCS 126 completely stops, but this current is not high enough or long enough to produce an undesirable amount of stray light.

In some embodiments of the present disclosure, as shown in FIG. 1, an auxiliary current source 128 may also be connected to the common node of Cout 110 and the laser diode 112. In some embodiments, the auxiliary current source 128 provides a small current (e.g., 1 mA) to the common node once Cout 110 is pre-biased and the VCCS 126 is no longer charging Cout 110. The current from the auxiliary current source 128 keeps Cout 110 charged even if there is some leakage from Cout 110.

The loop gain of the pre-bias circuit is configured to ensure reliable detection of the voltage rise during the test pulse by the derivator and VCCS. Specifically, the voltage rise detected by the derivative should generate enough voltage to control the voltage-controlled current source VCCS, enabling it to provide its maximum (programmable—clamped) current. If the gain is insufficient, the pre-bias process may fail to initiate or may terminate prematurely. Conversely, the gain of the derivative should not be excessively high to prevent sensitivity to system noise. Overall, the system gain must be set to facilitate the accurate and reliable generation of the pre-bias sequence, as illustrated in FIG. 2.

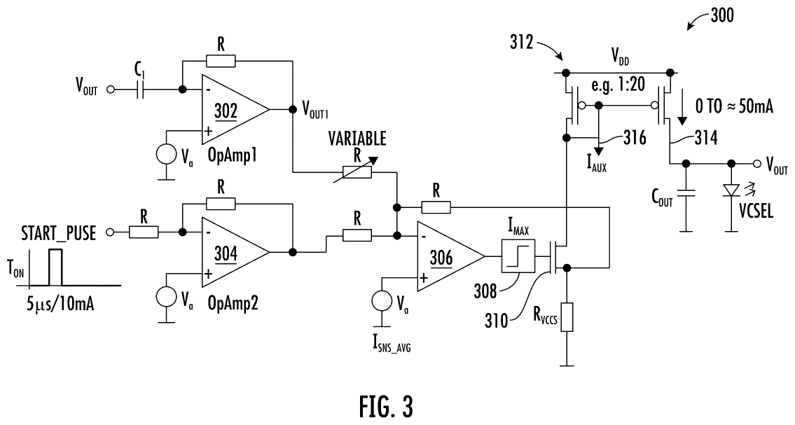

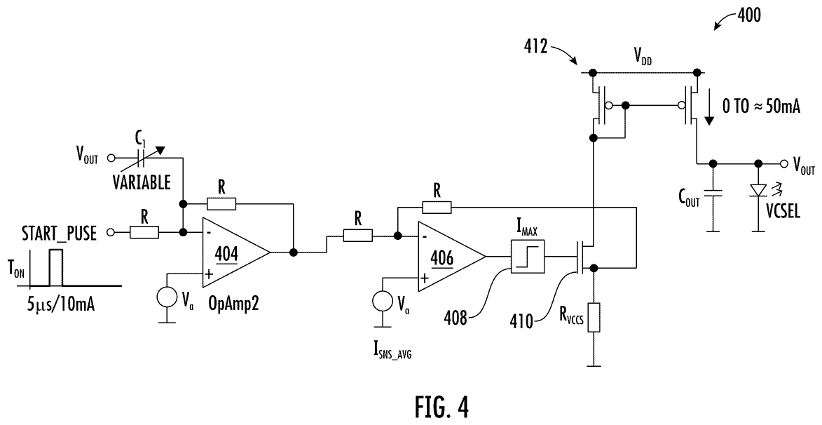

FIGS. 3 and 4 illustrate alternative example circuit diagrams of an example system for pre-biasing a laser diode driver, using three and two opamps, respectively, in accordance with some embodiments of the present disclosure. FIG. 3 illustrates an example circuit 300 comprising a derivator formed by OpAmp1 302, a startup circuit formed by OpAmp2 304 that provides the Start pre-bias voltage, a summing V/I convertor formed by OpAmp 306, a saturation block 308, an NMOS transistor 310, and a current mirror 312. FIG. 4 illustrates an example circuit 400 comprising a combined derivator and startup circuit formed by OpAmp2 404, a summing V/I convertor formed by OpAmp 406, and a saturation block 408, an NMOS transistor 410, and a current mirror 412.

The circuit examples in FIGS. 3 and 4 implement the high-level schematic from FIG. 1. In these circuits, OpAmp2 304 functions as a start-pulse generator, and OpAmp1 302 serves as the derivative element producing the output voltage proportional to the time derivative of the VCSEL pulsed generator output voltage V_{OUT}. The derivative capacitor of this element is connected to the output node V_{OUT}. The outputs of OpAmp1 302 and OpAmp 2 304, respectively V_{OUT1} and V_{OUT2}, are summed via resistances R. The resistances of the derivative element are adjustable, allowing the gain of the derivative element to be set to the optimal value, thereby enabling the optimal gain to be set and allowing the precharge sequence to be initiated and maintained.

The third OpAmp 306, along with the associated saturation block 308, NMOS transistor 310, and resistor R_{VCCS}, incorporates the voltage-controlled current source (VCCS). The input control voltage of the VCCS is the sum of V_{OUT1} and V_{OUT2}, and the output current is determined by applying this voltage sum, with a specific gain, to the resistance R_{VCCS}. The output current of the VCCS is available at the drain of the NMOS transistor 310. VCCS output current is connected to the input terminal of the current mirror 312, potentially incorporating some current gain (e.g. 1 or 20). The output terminal 314 of the current mirror 312 provides the output recharging current to the capacitor Cout.

This operational principle can be implemented by various other circuit topologies, such as using operational transconductance amplifiers (OTAs), different topologies of derivative element, or alternative current sources topologies. The VCCS current source implemented by the OpAmp3 can also be designed to drive the capacitor Cout directly from the power supply terminal V_{DD}, thus eliminating the need for the current mirror. The MOS transistor current mirror in FIG. 3 also includes an auxiliary (optional) current input 316 corresponding to the auxiliary current source 128 from FIG. 1 allowing to compensate the VCSEL diode leakage after the end of the prebias sequence. This compensation current can also be injected, directly to the output node, i.e., without using the current mirror. An alternative to the circuit in FIG. 3 is the circuit in FIG. 4, where the summing of the start pulse and the derivative function is implemented in a single OpAmp2, thus eliminating one operational amplifier. All amplifiers in FIGS. 3 and 4 operate with a common mode voltage Vₐ, which can be ground or any constant positive or negative voltage, depending on the voltage supply range.

### CONCLUSION

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

While this detailed description has set forth some embodiments of the present disclosure, the appended claims cover other embodiments of the present disclosure which differ from the described embodiments according to various modifications and improvements. For example, the appended claims can cover any form of suitable device having one or more diodes (such as silicon diodes, laser diodes, LEDs, etc.), including but not limited to time-of-flight modules having one or more VCSELs.

Within the appended claims, unless the specific term “means for” or “step for” is used within a given claim, it is not intended that the claim be interpreted under 35 U.S.C. 112, paragraph 6.

What is claimed is:

1. A pre-biasing circuit comprising:
a capacitor circuit connected between a common node and a ground;
a diode connected in parallel with the capacitor circuit between the common node and the ground;
a derivative circuit having an input and an output, the input being connected to the common node;
a summing circuit having a first input, a second input, and an output, the first input being connected to the output of the derivative circuit;
a pre-biasing current source with an input connected to the output of the summing circuit and an output connected to the common node; and
a test voltage source having an output connected to the second input of the summing circuit;
wherein the test voltage source is configured to output a predetermined test voltage for a predetermined amount of time to the second input of the summing circuit, which in turn causes the pre-biasing current source to inject a test current into the common node;
wherein, if a voltage at the common node is less than a forward voltage of the diode, the injected test current causes the voltage at the common node to increase, which in turn causes the derivative circuit to output a voltage corresponding to a rate of increase of the voltage at the common node to the first input of the summing circuit, which in turn causes the pre-biasing current source to inject a pre-biasing current into the common node; and
wherein, if the voltage at the common node is equal to or greater than the forward voltage of the diode, the voltage at the common node will not increase, which in turn causes the derivative circuit to not output a voltage to the first input of the summing circuit, which in turn causes the pre-biasing current source to not inject a pre-biasing current into the common node.

2. The pre-biasing circuit of claim 1, further comprising an operating current source having an output connected to the common node to provide an operating current to drive the diode.

3. The pre-biasing circuit of claim 2, wherein the operating current source comprises a direct current-to-direct current converter.

4. The pre-biasing circuit of claim 1, wherein the pre-biasing current is limited to a predefined maximum pre-biasing current.

5. The pre-biasing circuit of claim 4, further comprising an auxiliary current source connected in parallel to the pre-biasing current source and having an output connected to the common node to provide a predefined pre-bias maintenance current to the common node.

6. The pre-biasing circuit of claim 1, wherein the diode comprises one or more silicon diodes, one or more laser diodes, or one or more light emitting diodes.

7. The pre-biasing circuit of claim 6, wherein the one or more laser diodes comprise one or more vertical cavity surface emitting lasers.

8. A time-of-flight module comprising:
a capacitor circuit connected between a common node and a ground;
a laser diode circuit connected in parallel with the capacitor circuit between the common node and the ground;
a derivative circuit having an input and an output, the input being connected to the common node;
a summing circuit having a first input, a second input, and an output, the first input being connected to the output of the derivative circuit;
a pre-biasing current source with an input connected to the output of the summing circuit and an output connected to the common node; and
a test voltage source having an output connected to the second input of the summing circuit;
wherein the test voltage source is configured to output a predetermined test voltage for a predetermined amount of time to the second input of the summing circuit, which in turn causes the pre-biasing current source to inject a test current into the common node;
wherein, if a voltage at the common node is less than a forward voltage of the laser diode circuit, the injected test current causes the voltage at the common node to increase, which in turn causes the derivative circuit to output a voltage corresponding to a rate of increase of the voltage at the common node to the first input of the summing circuit, which in turn causes the pre-biasing current source to inject a pre-biasing current into the common node; and
wherein, if the voltage at the common node is equal to or greater than the forward voltage of the laser diode circuit, the voltage at the common node will not increase, which in turn causes the derivative circuit to not output a voltage to the first input of the summing circuit, which in turn causes the pre-biasing current source to not inject a pre-biasing current into the common node.

9. The time-of-flight module of claim 8, further comprising an operating current source having an output connected to the common node to provide an operating current to drive the laser diode circuit.

10. The time-of-flight module of claim 9, wherein the operating current source comprises a direct current-to-direct current converter.

11. The time-of-flight module of claim 8, wherein the pre-biasing current is limited to a predefined maximum pre-biasing current.

12. The time-of-flight module of claim 11, further comprising an auxiliary current source connected in parallel to the pre-biasing current source and having an output connected to the common node to provide a predefined pre-bias maintenance current to the common node.

13. The time-of-flight module of claim 12, wherein the predefined pre-bias maintenance current is less than ten percent of the predefined maximum pre-biasing current.

14. The time-of-flight module of claim 8, wherein the laser diode circuit comprises at least one vertical cavity surface emitting laser.

15. A method of pre-biasing a diode, the method comprising:
providing a pre-biasing circuit comprising:
a capacitor circuit connected between a common node and a ground;
a diode connected in parallel with the capacitor circuit between the common node and the ground;
a derivative circuit having an input and an output, the input being connected to the common node;
a summing circuit having a first input, a second input, and an output, the first input being connected to the output of the derivative circuit;
a pre-biasing current source with an input connected to the output of the summing circuit and an output connected to the common node; and
a test voltage source having an output connected to the second input of the summing circuit; and
outputting a predetermined test voltage for a predetermined amount of time from the test voltage source to the second input of the summing circuit, which causes the pre-biasing current source to inject a test current into the common node;
wherein, if a voltage at the common node is less than a forward voltage of the diode, the injected test current causes the voltage at the common node to increase, which in turn causes the derivative circuit to output a voltage corresponding to a rate of increase of the voltage at the common node to the first input of the summing circuit, which in turn causes the pre-biasing current source to inject a pre-biasing current into the common node; and
wherein, if the voltage at the common node is equal to or greater than the forward voltage of the diode, the voltage at the common node will not increase, which in turn causes the derivative circuit to not output a voltage to the first input of the summing circuit, which in turn causes the pre-biasing current source to not inject a pre-biasing current into the common node.

16. The method of claim 15, further comprising providing an operating current to drive the diode from an operating current source having an output connected to the common node.

17. The method of claim 16, wherein the operating current source comprises a direct current-to-direct current converter.

18. The method of claim 15, wherein the pre-biasing current is limited to a predefined maximum pre-biasing current.

19. The method of claim 18, further comprising providing a predefined pre-bias maintenance current to the common node from an auxiliary current source connected in parallel to the pre-biasing current source and having an output connected to the common node.

20. The method of claim 15, wherein the diode comprises one or more silicon diodes, one or more laser diodes, or one or more light emitting diodes.
